(19) United States
(12) Patent Application Publication
(10) Pub. No.: US 2015/0263036 A1
(43) Pub. Date: Sep. 17, 2015

(54) SEMICONDUCTOR MEMORY DEVICE

(71) Applicant: Kabushiki Kaisha Toshiba, Minato-ku (JP)

(72) Inventors: Naoki YASUDA, Mie (JP); Hideaki Aochi, Yokkaichi (JP)

(73) Assignee: Kabushiki Kaisha Toshiba, Minato-ku (JP)

(21) Appl. No.: 14/635,246

(22) Filed: Mar. 2, 2015

(30) Foreign Application Priority Data
Mar. 14, 2014 (JP) 2014-052169

(51) Int. Cl. H01L 27/115

(52) U.S. Cl. CPC H01L 27/11582

(57) ABSTRACT

According to one embodiment, the columnar section includes a first region having a first diameter and a second region having a second diameter smaller than the first diameter. The plurality of electrode layers include a first electrode layer adjacent to the first region and a second electrode layer adjacent to the first region, and a third electrode layer adjacent to the second region and a fourth electrode layer adjacent to the second region. A distance between the third electrode layer and the fourth electrode layer is smaller than a distance between the first electrode layer and the second electrode layer.

### CROSS-REFERENCE TO RELATED APPLICATION

This application is based upon and claims the benefit of priority from Japanese Patent Application No. 2014-052169, filed on Mar. 14, 2014; the entire contents of which are incorporated herein by reference.

### FIELD

Embodiments described herein relate generally to a semiconductor memory device.

### BACKGROUND

There has been proposed a memory device having a three-dimensional structure in which memory holes are formed in a stacked body formed by stacking, via insulating layers, a plurality of electrode layers functioning as control gates in memory cells and silicon bodies functioning as channels are provided on the sidewalls of the memory holes via charge storage films.

In a memory string in which a plurality of memory cells are connected in series in a stacking direction of electrode layers, a channel is induced by a fringe electric field of the electrode layers in a region adjacent to an interlayer insulating film between the memory cells. As the memory string is longer, the resistance of the induced channel between the memory cells contributes more to parasitic resistance of the memory string.

### BRIEF DESCRIPTION OF THE DRAWINGS

FIG. 1 is a schematic perspective view of a memory cell array of an embodiment;

FIG. 2 is a schematic sectional view of a memory string of the embodiment;

FIG. 3 is a schematic sectional view of a memory cell of the embodiment;

FIG. 4 is a schematic sectional view of a memory string of the embodiment;

FIGS. 5 to 9 are schematic sectional views showing a method for manufacturing a semiconductor device of the embodiment;

FIGS. 10A and 10B are schematic views showing simulation results of a reference example;

FIGS. 11A to 12 are schematic views showing simulation results of a first embodiment;

FIGS. 13A to 14 are schematic views showing simulation results of a second embodiment;

FIGS. 15A to 16 are schematic views showing simulation results of a third embodiment;

FIGS. 17A to 18B are schematic views showing simulation results of a fourth embodiment;

FIGS. 19A and 19B are schematic views showing simulation results of a fifth embodiment;

FIG. 20 is a schematic view showing simulation results of a reference example;

FIG. 21 is a schematic sectional view of a memory string of a sixth embodiment; and

FIG. 22 is a schematic perspective view of a memory cell array of an embodiment.

### DETAILED DESCRIPTION

According to one embodiment, a semiconductor memory device includes a stacked body including a plurality of electrode layers stacked via an insulator; and a columnar section including a channel body extending in a stacking direction of the stacked body in the stacked body, and a memory film provided between the channel body and the electrode layers. The columnar section includes a first region having a first diameter and a second region having a second diameter smaller than the first diameter. The plurality of electrode layers include a first electrode layer adjacent to the first region and a second electrode layer adjacent to the first region, and a third electrode layer adjacent to the second region and a fourth electrode layer adjacent to the second region. A distance between the third electrode layer and the fourth electrode layer is smaller than a distance between the first electrode layer and the second electrode layer.

An embodiment is described below with reference to the drawings. Note that, in the drawings, the same components are denoted by the same reference numerals and signs.

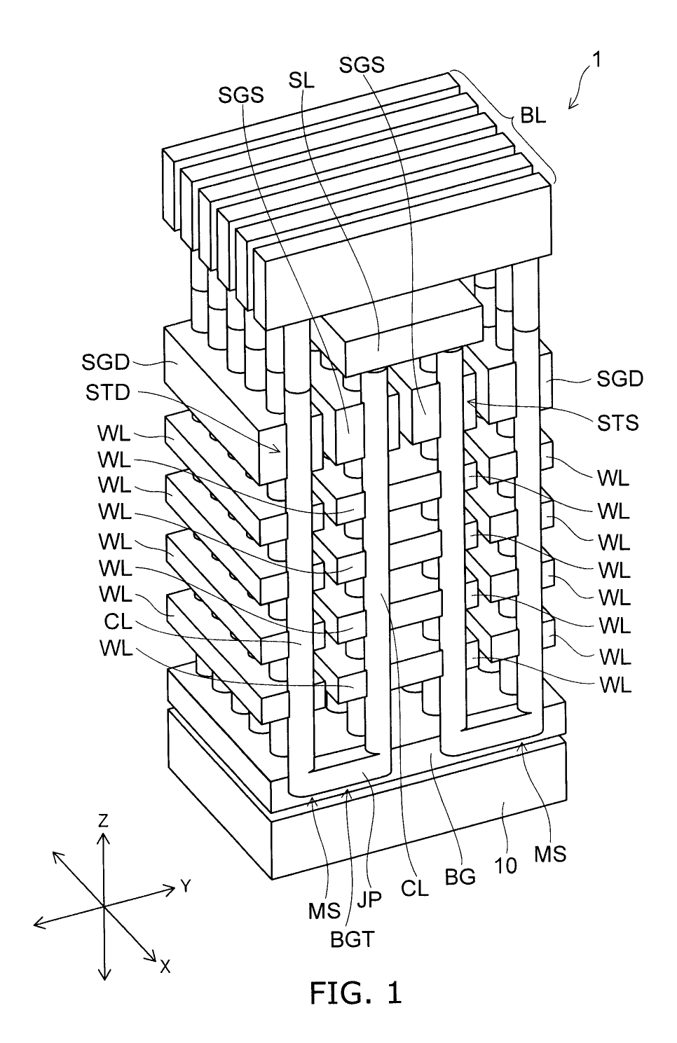

FIG. 1 is a schematic perspective view of a memory cell array 1 of a semiconductor memory device of the embodiment. Note that, in FIG. 1, illustration of insulating layers, isolation films, and the like is omitted to clearly show the figure.

In FIG. 1, two directions parallel to the major surface of a substrate 10 and orthogonal to each other are represented as an X-direction and a Y-direction. A direction orthogonal to both of the X-direction and the Y-direction is represented as a Z-direction (a stacking direction).

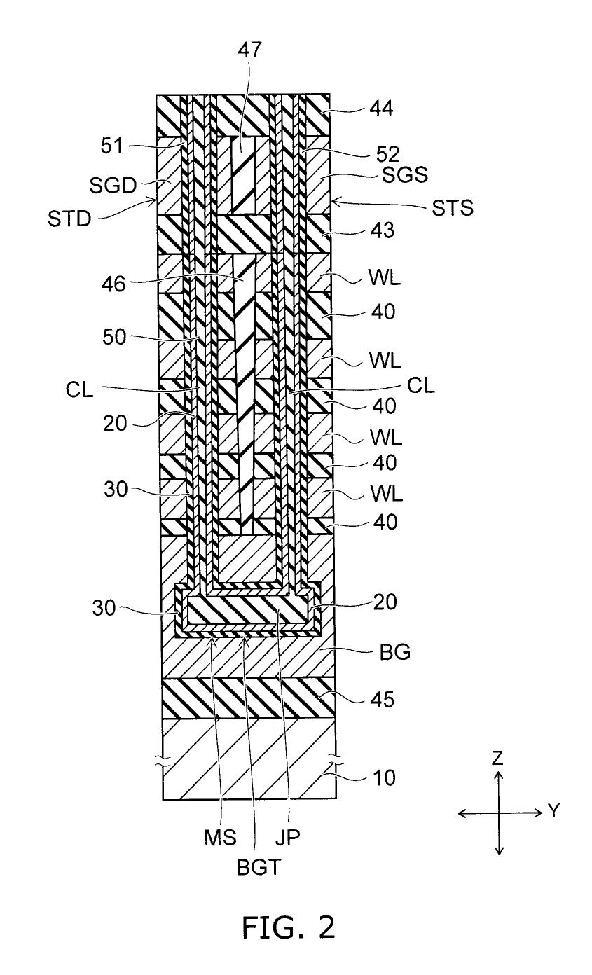

The memory cell array 1 includes a plurality of memory strings (NAND strings) MS. FIG. 2 is a schematic sectional view of the memory string MS. FIG. 2 shows a cross section parallel to a Y-Z plane in FIG. 1.

The memory cell array 1 includes a stacked body in which electrode layers WL and insulating layers 40 are alternately stacked. The stacked body includes a plurality of the electrode layers WL and a plurality of the insulating layers 40. The insulating layer 40 functioning as an insulator is provided between the electrode layer WL and the electrode layer WL. The insulator between the electrode layers WL may include an air gap.

The stacked body is provided on a back gate BG functioning as a lower gate layer. Note that the number of the electrode layers WL shown in the figure is an example. The number of the electrode layers WL may be any number.

The plurality of electrode layers WL include a first electrode layer and a second electrode layer provided further on the upper side than the center in the stacking direction of the stacked body and a third electrode layer and a fourth electrode layer provided further on the lower side than the center in the stacking direction of the stacked body.

The plurality of insulating layers 40 include a first insulating layer and a second insulating layer provided further on the upper side than the center in the stacking direction of the stacked body and a third insulating layer and a fourth insulating layer provided further on the lower side than the center in the stacking direction of the stacked body.

As described below, the thicknesses of the plurality of insulating layers 40 are not uniform and are varied. Each of the insulating layers 40 has different thickness. Alternatively, the thicknesses of the insulating layers 40 are varied stepwise in units of the plurality of insulating layers 40 adjacent to each other in the stacking direction.

The back gate BG is provided on the substrate 10 via an insulating layer 45. The back gate BG and the electrode layers WL are layers containing silicon as a main component. Further, the back gate BG and the electrode layers WL contain, for example, boron as impurities for imparting electric conductivity to a silicon layer. The electrode layers WL may contain metal silicide. The insulating layers 40 mainly contain, for example, silicon oxide.

One memory string MS is formed in a U shape including a pair of columnar sections CL extending in the Z-direction and a joining section JP that couples the lower ends of the pair of columnar sections CL. The columnar sections CL are formed in, for example, a cylindrical or elliptical columnar shape, pierce through the stacked body, and reach the back gate BG.

A drain side selection gate SGD is provided at the upper end portion of one of the pair of columnar sections CL in the U-shaped memory string MS. A source side selection gate SGS is provided at the upper end portion of the other. The drain side selection gate SGD and the source side selection gate SGS are provided on the top electrode layer WL via an interlayer insulating layer 43.

The drain side selection gate SGD and the source side selection gate SGS are layers containing silicon as a main component. Further, the drain side selection gate SGD and the source side selection gate SGS contain, for example, boron as impurities for imparting electric conductivity to a silicon layer.

The drain side selection gate SGD and the source side selection gate SGS functioning as upper selection gates and the back gate BG functioning as a lower selection gate are thicker than the electrode layer WL having the largest thickness.

The drain side selection gate SGD and the source side selection gate SGS are separated in the Y-direction by an isolation film 47. The stacked body under the drain side selection gate SGD and the stacked body under the source side selection gate SGS are separated in the Y-direction by an isolation film 46. That is, the stacked body between the pair of columnar sections CL of the memory string MS is separated in the Y-direction by the isolation films 46 and 47.

A source line (e.g., a metal film) SL shown in FIG. 1 is provided on the source side selection gate SGS via an insulating layer 44. A plurality of bit lines (e.g., metal films) BL shown in FIG. 1 are provided on the drain side selection gate SGD and the source line SL via the insulating layer 44. The bit lines BL extend in the Y-direction.

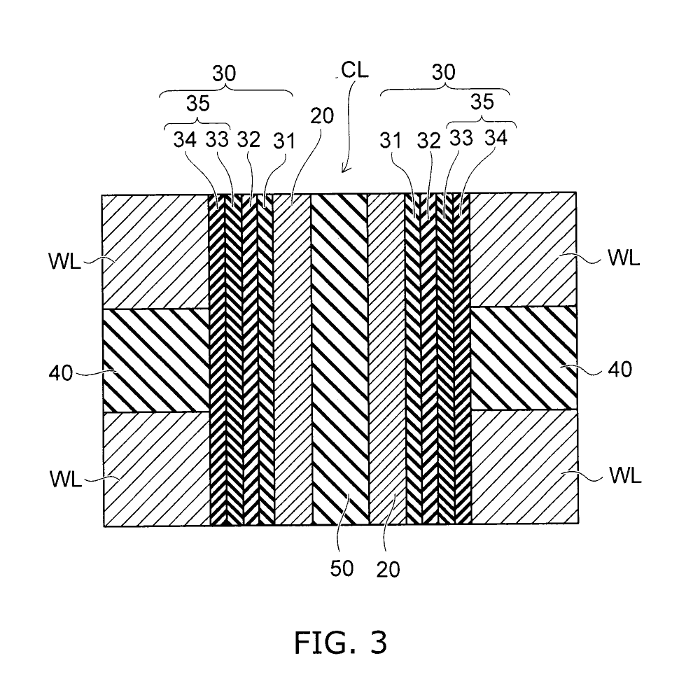

FIG. 3 is an enlarged schematic sectional view of a part of the columnar section CL.

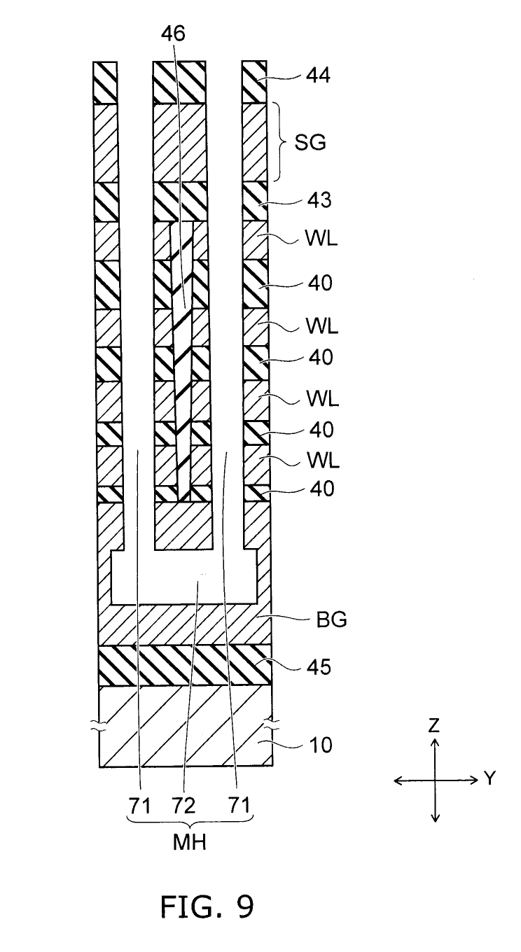

The columnar section CL is formed in a U-shaped memory hole MH shown in FIG. 9 described below. The memory hole MH is formed in the stacked body including the plurality of electrode layers WL, the plurality of insulating layers 40, and the back gate BG.

A channel body 20 functioning as a semiconductor channel is provided in the memory hole MH. The channel body 20 is, for example, a silicon film. The impurity concentration of the channel body 20 is lower than the impurity concentration of the electrode layers WL.

A memory film 30 is provided between the inner wall of the memory hole MH and the channel body 20. The memory film 30 includes a block insulating film 35, a charge storage film 32, and a tunnel insulating film 31.

The block insulating film 35, the charge storage film 32, and the tunnel insulating film 31 are provided in order from the electrode layers WL side between the electrode layers WL and the channel body 20.

The channel body 20 is provided in a cylindrical shape extending in the stacking direction of the stacked body. The memory film 30 is provided in a cylindrical shape while extending in the stacking direction of the stacked body to surround the outer circumferential surface of the channel body 20. The electrode layers WL surround the channel body 20 via the memory film 30. A core insulating film 50 is provided on the inner side of the channel body 20. The core insulating film 50 is, for example, a silicon oxide film.

The block insulating film 35 is in contact with the electrode layers WL. The tunnel insulating film 31 is in contact with the channel body 20. A charge storage film 32 is provided between the block insulating film 35 and the tunnel insulating film 31.

The channel body 20 functions as a channel in the memory cells. The electrode layers WL function as control gates of the memory cells. The charge storage film 32 functions as a data memory layer that accumulates electric charges injected from the channel body 20. That is, the memory cells having structure in which the control gates surround the channel are formed in crossing portions of the channel body 20 and the electrode layers WL.

The semiconductor memory device of the embodiment is a nonvolatile semiconductor memory device in which data can be electrically freely erased and written and stored contents can be retained even if a power supply is turned off.

The memory cells are, for example, memory cells of a charge trap type. The charge storage film 32 includes a large number of trap sites that capture electric charges and is, for example, a silicon nitride film (an Si₃N₄ film).

The tunnel insulating film 31 functions as a potential barrier when electric charges are injected into the charge storage film 32 from the channel body 20 or when electric charges accumulated in the charge storage film 32 diffuse to the channel body 20. The tunnel insulating film 31 is, for example, a silicon oxide film (an SiO₂ film).

As the tunnel insulating film, a stacked film (an ONO film) having structure in which a silicon nitride film is sandwiched by a pair of silicon oxide films may be used. When the ONO film is used as the tunnel insulating film, an erasing operation can be performed with a low electric field compared with a single layer of a silicon oxide film.

The block insulating film 35 prevents the electric charges accumulated in the charge storage film 32 from being discharged to the electrode layers WL. The block insulating film 35 includes a cap film 34 provided in contact with the electrode layers WL and a block film 33 provided between the cap film 34 and the charge storage film 32.

The block film 33 is, for example, a silicon oxide film (an SiO₂ film). The cap film 34 is a film having a dielectric constant higher than the dielectric constant of silicon oxide and is, for example, a silicon nitride film (an Si₃N₄ film). By providing the cap film 34 in contact with the electrode layers WL, it is possible to suppress back tunnel electrons injected from the electrode layers WL during erasing. That is, by using a stacked film of the silicon oxide film and the silicon nitride film as the block insulating film 35, it is possible to improve a charge blocking property.

As the cap film 34, high-k insulating films such as an aluminum oxide film (an Al₂O₃ film), a hafnium oxide film (an HfO₂ film), a hafnium aluminate film (an HfAlO film), and a lanthanum aluminate film (an LaAlO film) may be used. The cap film 34 may be a stacked film of at least any one of the aluminum oxide film, the hafnium oxide film, the hafnium aluminate film, and the lanthanum aluminate film and the silicon nitride film.

As shown in FIGS. 1 and 2, a drain side selection transistor STD is provided at the upper end portion of one of the pair of columnar sections CL in the U-shaped memory string MS. A source side selection transistor STS is provided at the upper end portion of the other.

The memory cells, the drain side selection transistor STD, and the source side selection transistor STS are vertical transistors in which an electric current flows in the stacking direction of the stacked body stacked on the substrate 10 (the Z-direction).

The drain side selection gate SGD functions as a gate electrode (a control gate) of the drain side selection transistor STD. An insulating film 51 (FIG. 2) functioning as a gate insulating film of the drain side selection transistor STD is provided between the drain side selection gate SGD and the channel body 20. The channel body 20 of the drain side selection transistor STD is connected to the bit lines BL above the drain side selection gate SGD.

The source side selection gate SGS functions as a gate electrode (a control gate) of the source side selection transistor STS. An insulating film 52 (FIG. 2) functioning as a gate insulating film of the source side selection transistor STS is provided between the source side selection gate SGS and the channel body 20. The channel body 20 of the source side selection transistor STS is connected to the source line SL above the source side selection gate SGS.

A back gate transistor BGT is provided in the joining section JP of the memory string MS. The back gate BG functions as a gate electrode (a control gate) of the back gate transistor BGT. The memory film 30 provided in the back gate BG functions as a gate insulating film of the back gate transistor BGT.

A plurality of memory cells including the respective electrode layers WL as control gates are provided between the drain side selection transistor STD and the back gate transistor BGT. Similarly, a plurality of memory cells including the respective electrode layers WL as control gates are also provided between the back gate transistor BGT and the source side selection transistor STS.

The plurality of memory cells, the drain side selection transistor STD, the back gate transistor BGT, and the source side selection transistor STS are connected in series through the channel body 20 to configure U-shaped one memory string MS. A plurality of the memory strings MS are arrayed in the X-direction and the Y-direction, whereby the plurality of memory cells are three-dimensionally provided in the X-direction, the Y-direction, and the Z-direction.

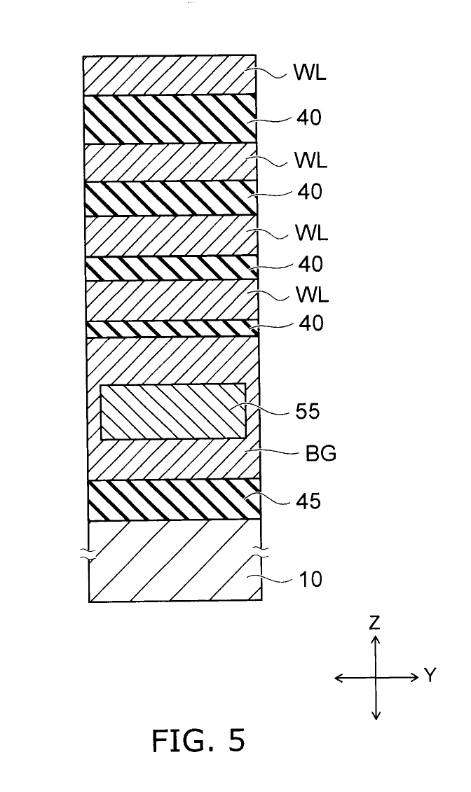

A manufacturing method for the semiconductor memory device of the embodiment is described with reference to FIGS. 5 to 9.

As shown in FIG. 5, the back gate BG is formed on the substrate 10 via the insulating layer 45. A recessed section is formed in the back gate BG. A sacrificial film 55 is embedded in the recessed section. The sacrificial film 55 is, for example, a silicon nitride film.

On the back gate BG, the plurality of insulating layers 40 and the plurality of electrode layers WL are alternately stacked. The insulating films 40 and the electrode layers WL are formed by, for example, a CVD (Chemical Vapor Deposition) method. The thickness of the insulating layer 40 and the thickness of the electrode layer WL can be arbitrarily controlled according to control of a gas flow rate, a film formation time, and the like in the formation.

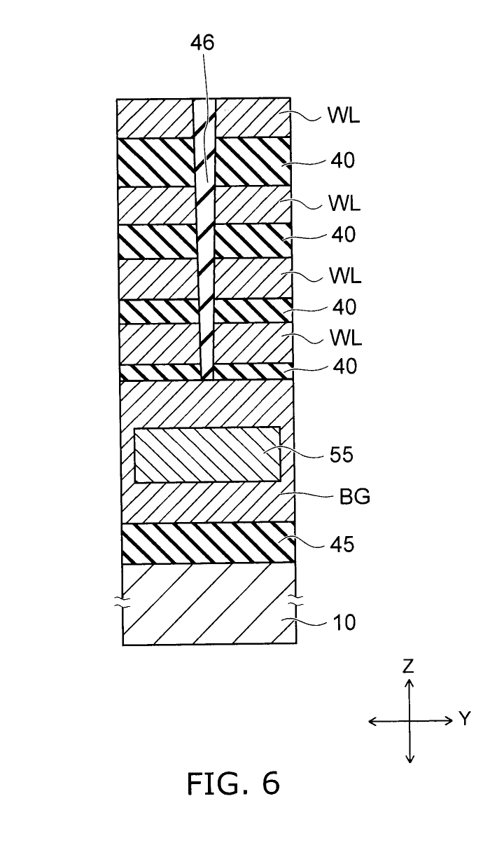

After the stacked body including the electrode layers WL and the insulating layers 40 is formed, a slit is formed in the stacked body to separate the stacked body in the Y-direction. In the slit, as shown in FIG. 6, the isolation film 46 is embedded. The isolation film 46 is, for example, a silicon nitride film.

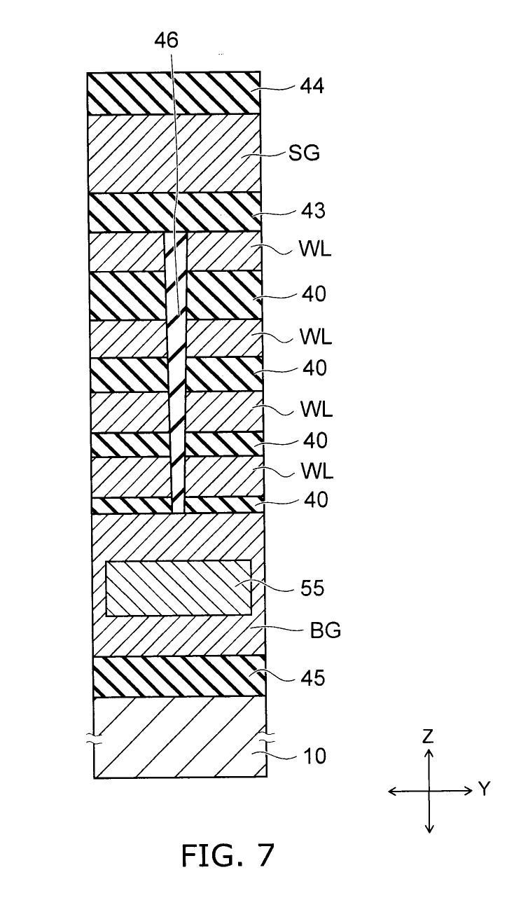

After the isolation film 46 is formed, as shown in FIG. 7, the insulating layer 43 is formed on the top electrode layer WL. An upper selection gate SG, which changes to the drain side selection gate SGD or the source side selection gate SGS, is formed on the insulating layer 43. The insulating layer 44 is formed on the upper selection gate SG.

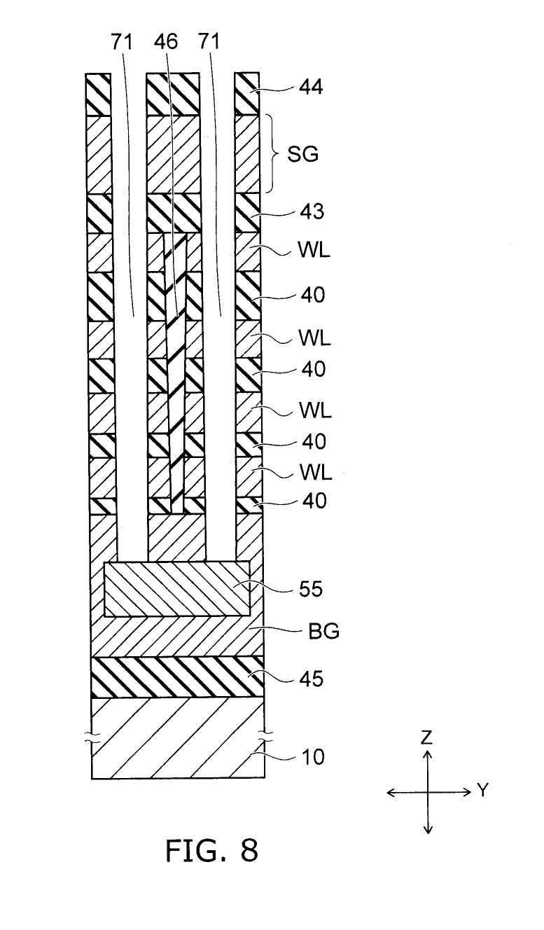

Subsequently, as shown in FIG. 8, a plurality of holes 71 are formed in the stacked body. The holes 71 are formed by, for example, an RIE (Reactive Ion Etching) method using a not-shown mask.

The lower ends of the holes 71 reach the sacrificial film 55. The sacrificial film 55 is exposed in the bottoms of the holes 71. A pair of the holes 71 is formed on one sacrificial film 55.

After the holes 71 are formed, the sacrificial film 55 is removed by etching through the holes 71. The sacrificial film 55 is removed by, for example, wet etching.

A recessed section 72 formed in the back gate BG is formed by the removal of the sacrificial film 55 as shown in FIG. 9. The pair of holes 71 is connected to one recessed section 72. That is, the lower ends of the pair of holes 71 are connected to one common recessed section 72 to form one U-shaped memory hole MH.

After the memory hole MH is formed, the films shown in FIG. 3 are formed in order on the inner wall of the memory hole MH.

After the memory film 30, the channel body 20, and the core insulating film 50 are formed in the memory hole MH, as shown in FIG. 2, the upper selection gate SG between the pair of columnar sections CL is separated in the Y-direction by the isolation film 47.

Thereafter, the source line SL, the bit lines BL, and the like shown in FIG. 1 are formed on the insulating layer 44.

As described above, after the plurality of electrode layers WL and the plurality of insulating layers 40 are stacked, the holes 71 are collectively formed in the layers (FIG. 8). In this case, if the current process technique is used, a hole diameter is not always uniform from the upper layers to the lower layers of the stacked body. In many cases, the hole diameter tends to be large in the upper layers and small in the lower layers.

Such non-uniformity of the hole diameter causes an increase in parasitic resistance of the memory string. The parasitic resistance represents a total of series resistances present in portions other than the memory cells in the memory string.

Therefore, according to the embodiment, a reduction in the parasitic resistance is attained by adjusting the distance between the electrode layers according to the hole diameter. The distance between the electrode layers represents a minimum distance between the electrode layers WL adjacent to each other in the stacking direction across the insulating layer 40. When only the insulating layer 40 is formed between the electrode layers WL adjacent to each other in the stacking direction, the distance between the electrode layers corresponds to the thickness in the stacking direction of the insulating layer 40. In the following description, for convenience of description, it is assumed that the distance between the electrode layers is equivalent to the thickness of the insulating layer 40.

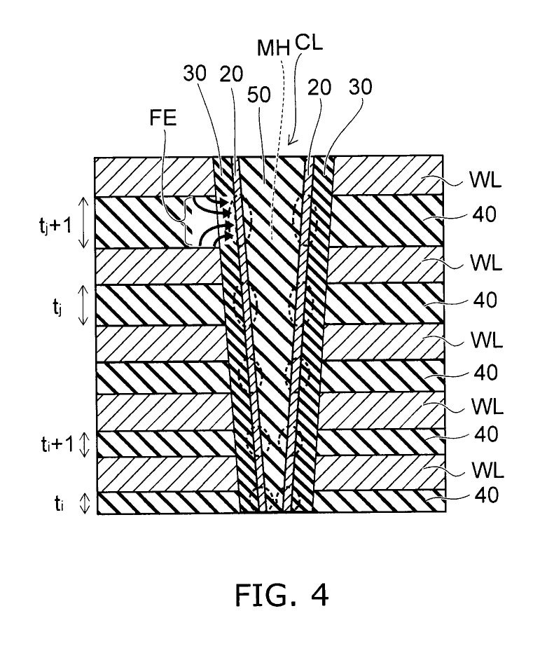

In the string of the three-dimensional memory cells formed by collectively processing the memory hole as described above, a diffusion layer of high-concentration impurities is absent between the memory cells adjacent to each other in the stacking direction. Therefore, a pass voltage (Vpass) is applied to the electrode layers WL of the memory cells adjacent to each other in the stacking direction. Channels (inversion layers) are induced in the channel body 20 in regions among the memory cells by a fringe electric field (schematically indicated by an arrow FE in FIG. 4) leaking from the electrode layers WL of the memory cells. The memory cells are connected in series in the stacking direction via the channels of these induced transistors. The channels are induced by the fringe electric field in regions surrounded by broken lines in FIG. 4.

A resistance value Rₚₐᵣₐ of the channels induced by the fringe electric field is represented by the following expression:

$${R}_{para} = \frac{{T}_{ins}}{2 π ( {D}_{MH} / 2 - {T}_{MONOS} ) {Q}_{ind} μ}$$

In the expression, Tᵢₙₛ represents the thickness of the insulating layer 40, D_{MH} represents the diameter of the memory hole in the position of the insulating layer 40, T_{MONOS} represents the thickness of the memory film 30, Q_{ind} represents the surface density of channel charges induced by the fringe electric field, and 11 represents the mobility of electrons in the induced channels (the inversion layers).

Channel width W of the induced transistor in the inter-electrode region (the insulating layer region) is W=2π (D_{MH}/2−T_{MONOS}). Channel length L of the transistor is L=Tᵢₙₛ.

There is also charge density Q_{ind} as a factor that determines Rₚₐᵣₐ. However, Q_{ind} is an amount having dependency of approximately a logarithm of D_{MH}. Therefore, what affects Rₚₐᵣₐ most is the channel width W and the channel length L of the induced transistors.

Usually, the memory film 30 deposited by a CVD (Chemical Vapor Deposition) method, an ALD (Atomic Layer Deposition) method, or the like has substantially uniform thickness in the stacking direction of the stacked body. Therefore, if the memory film 30 is thick, the channel width W=2π (D_{MH}/2−T_{MONOS}) of the induced transistor is excessively small in a region (a lower layer region) where the memory hole diameter D_{MH} is small. Therefore, Rₚₐᵣₐ increases unless the channel length L=Tᵢₙₛ is also reduced according to the reduction in W under such a situation.

From the above examination, in order to suppress the parasitic resistance of the entire string, it is effective to reduce the channel length L of the induced transistors in the region (the lower layer) where the hole diameter is small. Conversely, in the region (the upper layer) where the hole diameter is large, since the channel width W is large, Rₚₐᵣₐ is affected little even if the channel length L fluctuates more or less.

Therefore, in order to reduce the parasitic resistance under a condition that the total thickness of the plurality of insulating layers 40 in the stacked body including the memory cells is fixed, it is desired to perform thickness distribution of the insulating layer 40 to form the insulating layer 40 thick in the region (the upper layer) where the hole diameter is large and form the insulating layer 40 thin in the region (the lower layer) where the hole diameter is small. Note that the total thickness of the insulating layer 40 cannot be excessively reduced when a dielectric breakdown voltage between the electrode layers WL is taken into account. On the other hand, an average dielectric breakdown voltage can be secured if the total thickness of the insulating layers 40 is kept fixed. Therefore, it is appropriate to use the total thickness as a constraint in optimization of the memory cell structure.

If the total thickness of the insulating layer 40 is fixed and the height of the string (the stacked body height) is set to be not larger than the height of the existing structure, a burden is not imposed on memory hole processing.

As described above, the memory hole tends to have the large hole diameter on the upper layer side and have the small hole diameter on the lower layer side. Therefore, as shown in FIG. 4, the columnar section CL provided in the memory hole is formed in a shape including an upper section and a lower section having a diameter smaller than the diameter of the upper section. Note that the distance in the stacking direction between the upper section and the substrate 10 is larger than the distance in the stacking direction between the lower section and the substrate 10.

The circumferential direction length of the channel body 20 corresponds to the channel width W of the memory cell transistor and the induced transistor. The circumferential direction length (the channel width W) of the channel body 20 further on the lower side than the center in the stacking direction is smaller than the circumferential direction length (the channel width W) of the channel body 20 further on the upper side than the center in the stacking direction.

For example, in the example shown in FIG. 4, the thickness of the insulating layer 40 further on the lower layer side than the center in the stacking direction is smaller than the thickness of the insulating layer 40 on the upper layer side. The thickness of the insulating layer 40 adjacent to the lower section of the columnar section CL is smaller than the thickness of the insulating layer 40 adjacent to the upper section of the columnar section CL.

That is, the distance between the third electrode layer and the fourth electrode layer further on the lower layer side than the center in the stacking direction is smaller than the distance between the first electrode layer and the second electrode layer further on the upper layer side than the center in the stacking direction.

If the hole diameter (the diameter of the columnar section CL) is large, the channel width W of the induced transistor is large. Therefore, even if the insulating layers 40 are formed thick (the channel length L is increased), an increase amount of the resistance value Rₚₐᵣₐ of the induced channel is not conspicuous.

In a region where the diameter of the columnar section CL is large, compared with the region where the diameter of the columnar section CL is small, an electric field is less easily applied to the tunnel insulating film and data is less easily written. Therefore, in the region where the diameter of the columnar section CL is large, compared with the region where the diameter of the columnar section CL is small, a high programming voltage (applied voltage to the electrode layers WL) is required. Therefore, it is also desired to form the insulating layers 40 thicker on the upper layer side than the lower layer side from the viewpoint of securing a dielectric breakdown voltage between the electrode layers WL, which corresponds to the high programming voltage.

On the other hand, if the hole diameter (the diameter of the columnar section CL) is small, the channel width W of the induced transistor is small. Therefore, it is effective for a reduction in the parasitic resistance Rₚₐᵣₐ of the entire memory string to form the insulating layers 40 thin (reduce the channel length L). Note that, in the region where the diameter of the columnar section CL is small, compared with the region where the diameter of the columnar section CL is large, an electric field is easily applied to the tunnel insulating film and data is easily written. Therefore, in the region where the diameter of the columnar section CL is small, compared with the region where the diameter of the columnar section CL is large, it is possible to attain desired writing condition with a low programming voltage (applied voltage to the electrode layers WL). Therefore, it is possible to form the insulating layers 40 thinner on the lower layer side in accordance with the low programming voltage.

In the embodiment, on the lower layer side where the width W of the channel induced in the inter-electrode region by the fringe electric field is small compared with the upper layer side, the thickness of the insulating layer 40 is set small compared with the upper layer side. That is, the channel length L of the induced channel on the lower layer side is set small compared with the upper layer side.

Consequently, it is possible to reduce the total of the resistances of the channel induced by the fringe electric field (the parasitic resistance of the memory string).

The reduction in the parasitic resistance of the memory string has an effect of reducing back-pattern noise of a threshold voltage. The back-pattern noise means that a channel current of memory cells decreases and a threshold voltage shift occurs when a number of memory cell transistors in a programming state at a high threshold voltage level increases in one memory string.

In the semiconductor memory device having the three-dimensional structure described above, since the channel body 20 is formed in the stacking direction (the longitudinal direction) of the stacked body on the substrate, the channel body 20 of polycrystalline or amorphous silicon without a diffusion layer is used and a large cell current is not expected. Therefore, if another memory cell transistor connected to the same string is written until a threshold voltage reaches the largest level, a cell current drops to near a sense level of a sense amplifier. This causes an apparent threshold voltage shift. To avoid this phenomenon, it is necessary to reduce the parasitic resistance of the memory string as much as possible and increase a base level of the cell current.

Consequently, according to the embodiment, it is possible to increase the level of the cell current and realize memory cells robust against the back-pattern noise through the reduction in the parasitic resistance of the memory string.

Results obtained by calculating the resistance of the induced channel by the fringe electric field through a simulation are described concerning a reference example and first to fifth embodiments.

### Reference Example

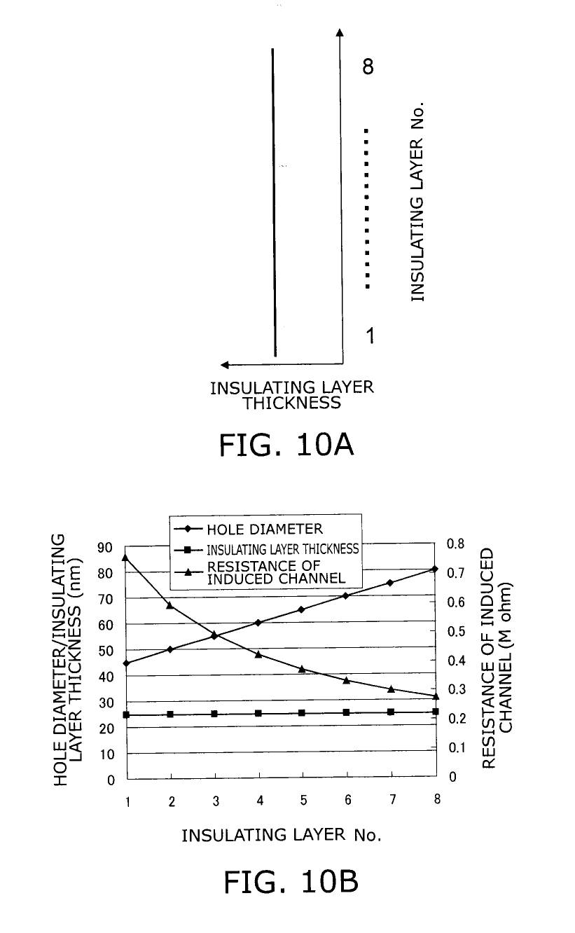

FIG. 10A is a schematic view showing a thickness change in the stacking direction of the insulating layers 40 in the reference example. The abscissa represents the thicknesses of the insulating layers 40 and the ordinate represents layer numbers (insulating layer Nos.) of the insulating layers 40.

The number of stacked layers of the electrode layers WL and the number of stacked layers of the insulating layers 40 are eight. An insulating layer No. 1 is associated with the bottom insulating layer 40 adjacent under the bottom electrode layer WL. An insulating layer No. 2 is associated with the second insulating layer 40 from the bottom adjacent under the second electrode layer WL from the bottom. Similarly, insulating layer Nos. 3, 4, 5, 6, 7, and 8 are respectively associated with third, fourth, fifth, sixth, seventh, and eighth insulating layers 40 from the bottom respectively adjacent under the third, fourth, fifth, sixth, seventh, and eighth electrode layers WL from the bottom. The same applies to the first to fifth embodiments.

The thicknesses of the eight electrode layers WL are uniform in the reference example and the first to fifth embodiments.

FIG. 10B is a graph representing a relation among the insulating layer No., a hole diameter (nm), the thickness (nm) of the insulating layer 40, and the resistance (M ohm) of the induced channel by the fringe electric field in the reference example. The hole diameter corresponds to the diameter of the columnar section CL.

The hole diameter gradually decreases from the upper layers to the lower layers. The hole diameter is the largest (80 nm) in the position of the top insulating layer 40 and is the smallest (45 nm) in the position of the first insulating layer 40. The same applies to the first to fourth embodiments.

The thickness of the memory film 30 is 18 nm. The thickness of the cap film (the Si₃N₄ film) 34 is 3 nm, the thickness of the block film (the SiO₂ film) 33 is 6 nm, the thickness of the charge storage film (the Si₃N₄ film) 32 is 5 nm, and the thickness of the tunnel insulating film (the SiO₂ film) 31 is 4 nm. The same applies to the first to fifth embodiments.

Note that the thickness configuration of the memory film 30 is only an example, and another thickness configuration may be used. In that case, the parasitic resistance value of the memory string is different from the parasitic resistance value in the embodiments. However, a correspondence relation between a control method for the thickness of the insulating layer 40 and a manifestation of a reduction in the parasitic resistance should not be different.

The total thickness of the eight insulating layers 40 is 200 nm. The same applies to the first to fifth embodiments.

In the reference example, the thicknesses of the eight insulating layers 40 are the same fixed value (25 nm). Therefore, a difference between a maximum and a minimum of the thicknesses in the eight insulating layers 40 is 0.

The parasitic resistance of the memory string (a total of channel resistances of the induced transistors) in the reference example is 3.56 MΩ.

### First Embodiment

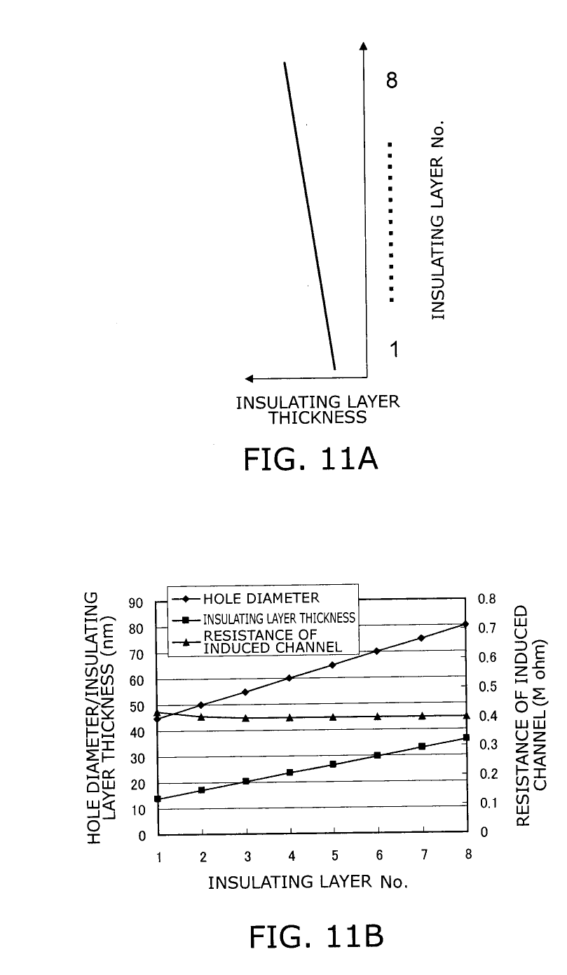

FIG. 11A is a schematic view showing a thickness change in the stacking direction of the insulating layers 40 in the first embodiment. The abscissa represents the thicknesses of the insulating layers 40 and the ordinate represents layer numbers (insulating layer Nos.) of the insulating layers 40.

FIG. 11B is a graph representing a relation among the insulating layer No., a hole diameter (nm), the thickness (nm) of the insulating layer 40, and the resistance (M ohm) of the induced channel by the fringe electric field in the first embodiment.

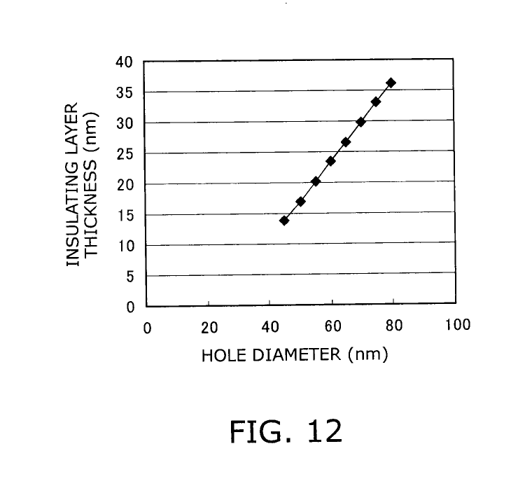

FIG. 12 is a graph representing a relation between the hole diameter (nm) and the thickness (nm) of the insulating layer 40 in the first embodiment.

In the first embodiment, the thicknesses of the eight insulating layers 40 linearly change as a linear function of the hole diameter. That is, the thicknesses decrease in every layer from the eighth insulating layer 40 to the first insulating layer 40.

The thickness of the thickest eighth insulating layer 40 is 36.2 nm. The thickness of the thinnest first insulating layer 40 is 13.8 nm. A difference between a maximum and a minimum of the thicknesses of the insulating layers 40 is 22.4 nm.

The parasitic resistance of the memory string (a total of channel resistances of the induced transistors) in the first embodiment is 3.22 MΩ. The parasitic resistance of the first embodiment is 9.6% lower than that of the reference example.

### Second Embodiment

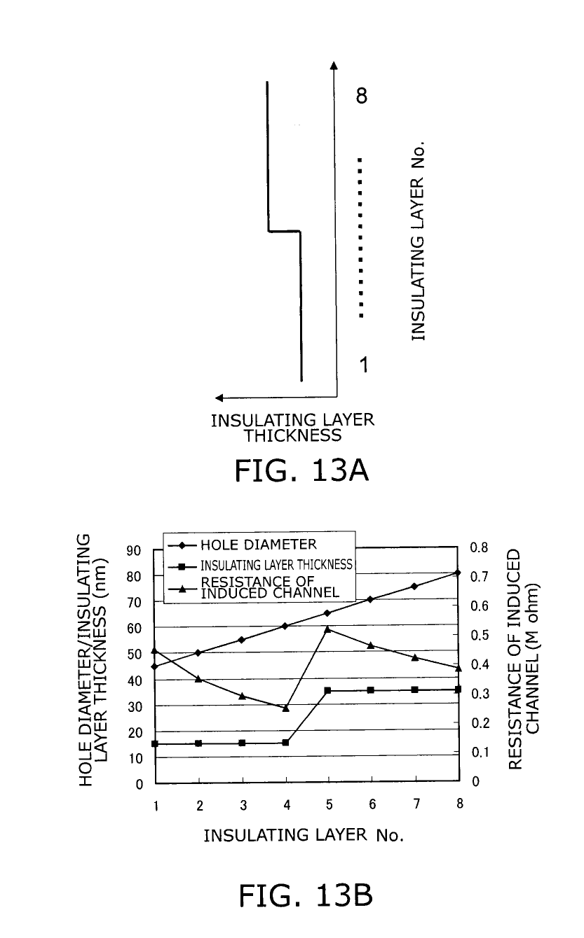

FIG. 13A is a schematic view showing a thickness change in the stacking direction of the insulating layers 40 in the second embodiment. The abscissa represents the thicknesses of the insulating layers 40 and the ordinate represents layer numbers (insulating layer Nos.) of the insulating layers 40.

FIG. 13B is a graph representing a relation among the insulating layer No., a hole diameter (nm), the thickness (nm) of the insulating layer 40, and the resistance (M ohm) of the induced channel by the fringe electric field in the second embodiment.

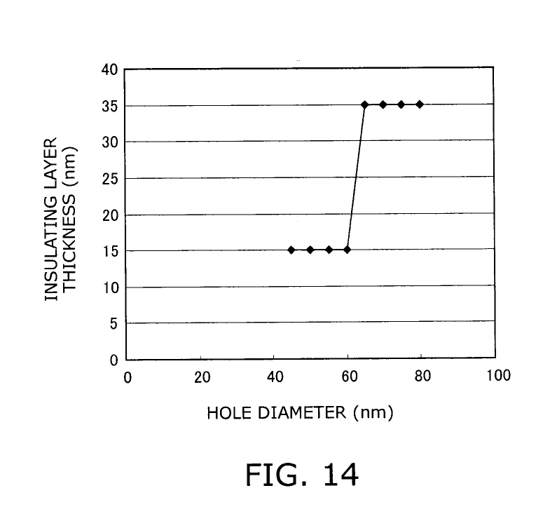

FIG. 14 is a graph representing a relation between the hole diameter (nm) and the thickness (nm) of the insulating layer 40 in the second embodiment.

In the second embodiment, among the eight insulating layers 40, the thicknesses of upper side four insulating layers 40 are set to 35 nm, while the thicknesses of the lower side four insulating layers 40 are set to 15 nm. The thicknesses of the lower side four insulating layers 40 are thinner than the thicknesses of the upper side four layers. A difference between a maximum and a minimum of the thicknesses of the insulating layers 40 is 20 nm.

The parasitic resistance of the memory string (a total of channel resistances of the induced transistors) in the second embodiment is 3.16 MΩ. The parasitic resistance of the second embodiment is 11.2% lower than that of the reference example.

### Third Embodiment

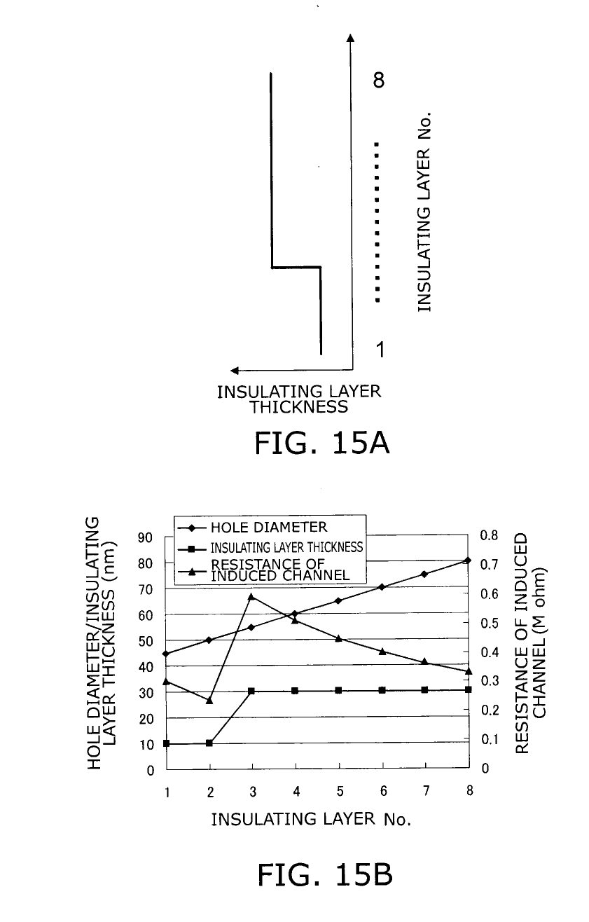

FIG. 15A is a schematic view showing a thickness change in the stacking direction of the insulating layers 40 in the third embodiment. The abscissa represents the thicknesses of the insulating layers 40 and the ordinate represents layer numbers (insulating layer Nos.) of the insulating layers 40.

FIG. 15B is a graph representing a relation among the insulating layer No., a hole diameter (nm), the thickness (nm) of the insulating layer 40, and the resistance (M ohm) of the induced channel by the fringe electric field in the third embodiment.

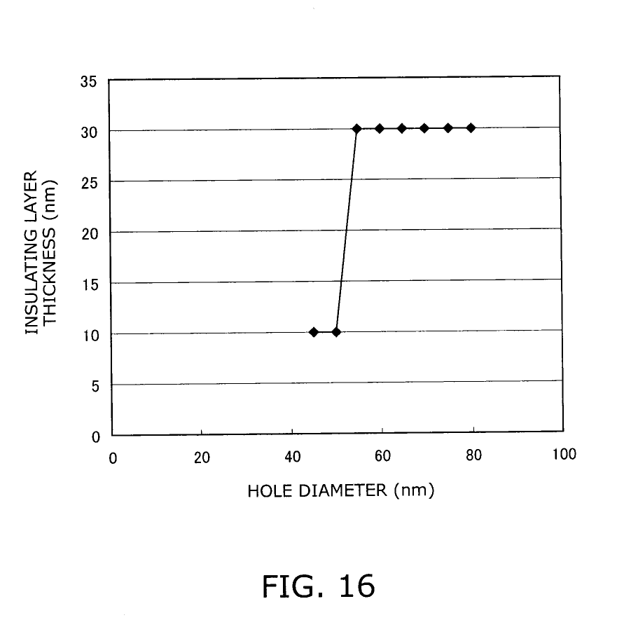

FIG. 16 is a graph representing a relation between the hole diameter (nm) and the thickness (nm) of the insulating layer 40 in the third embodiment.

In the third embodiment, among the eight insulating layers 40, the thicknesses of upper side six insulating layers 40 are set to 30 nm, while the thicknesses of the lower side two insulating layers 40 are set to 10 nm. The thicknesses of the lower side two insulating layers 40 are thinner than the thicknesses of the upper side six layers. A difference between a maximum and a minimum of the thicknesses of the insulating layers 40 is 20 nm.

The parasitic resistance of the memory string (a total of channel resistances of the induced transistor) in the third embodiment is 3.19 mΩ. The parasitic resistance of the third embodiment is 10.4% lower than that of the reference example.

### Fourth Embodiment

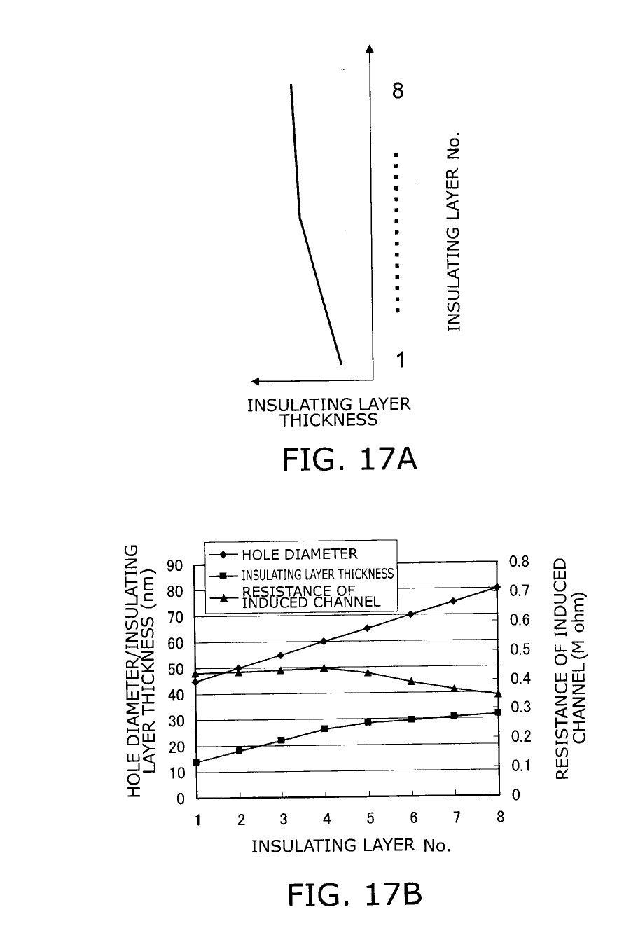

FIG. 17A is a schematic view showing a thickness change in the stacking direction of the insulating layers 40 in the fourth embodiment. The abscissa represents the thicknesses of the insulating layers 40 and the ordinate represents layer numbers (insulating layer Nos.) of the insulating layers 40.

FIG. 17B is a graph representing a relation among the insulating layer No., a hole diameter (nm), the thickness (nm) of the insulating layer 40, and the resistance (M ohm) of the induced channel by the fringe electric field in the fourth embodiment.

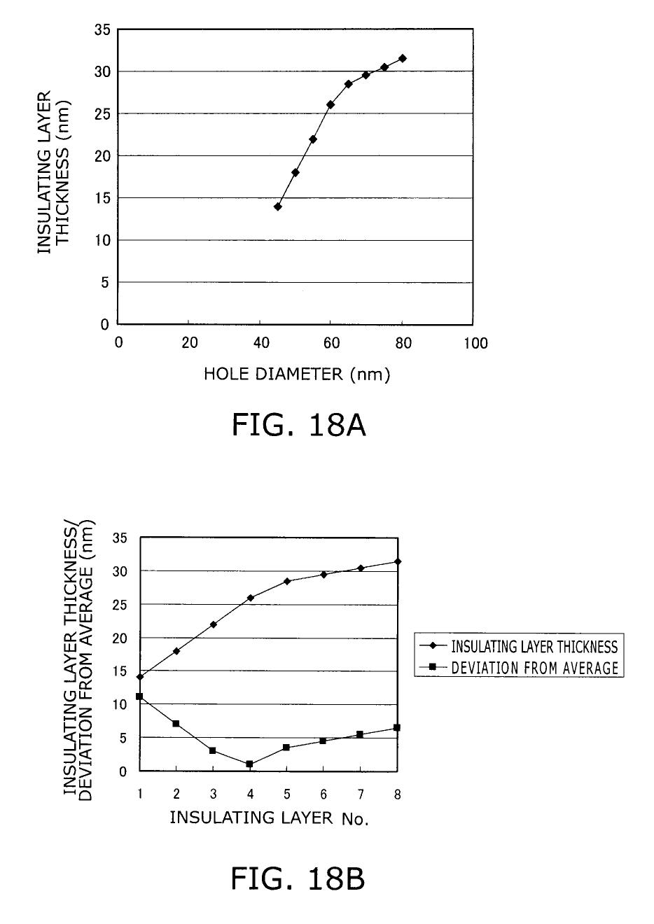

FIG. 18A is a graph representing a relation between the hole diameter (nm) and the thickness (nm) of the insulating layer 40 in the fourth embodiment.

FIG. 18B is a graph representing a relation among the insulating layer No., the thickness (nm) of the insulating layer 40, and a deviation (nm) from an average of the thickness of the insulating layer 40 in the fourth embodiment.

In the fourth embodiment, the thicknesses of the eight insulating layers 40 show sectional linear change with respect to the hole diameter. That is, a rate of change of the thicknesses of the lower side four insulating layers 40 is larger than a rate of change of the thicknesses of the upper side four insulating layers 40.

For example, when the thickness of any lower side insulating layer 40 is represented as tᵢ, the thickness of the insulating layer 40 immediately above the lower side insulating layer 40 is represented as tᵢ₊₁, the thickness of any upper side insulating layer 40 is represented as tⱼ, and the thickness of the insulating layer 40 right above the upper side insulating layer is represented as tⱼ₊₁, tᵢ₊₁−tᵢ>tⱼ₊₁−tⱼ holds.

A deviation with respect to average thickness of the eight insulating layers 40 is the largest in the bottom (first) insulating layer 40. A deviation from the average thickness of the top (eighth) insulating layer is smaller than a deviation of the bottom insulating layer 40.

That is, when the hole diameter is smaller in a lower section, the channel width W is smaller in a lower layer and a channel current further decreases. Therefore, a reduction ratio of the thickness of the insulating layer 40 (the channel length L) is increased toward the lower layer.

The thickness of the thickest eighth insulating layer 40 is 31.5 nm. The thickness of the thinnest first insulating layer 40 is 14 nm. A difference between a maximum and a minimum of the thicknesses of the insulating layers 40 is 17.5 nm.

The parasitic resistance of the memory string (a total of channel resistances of the induced transistors) in the fourth embodiment is 3.27 MΩ. The parasitic resistance of the third embodiment is 8.1% lower than that of the reference example.

### Fifth Embodiment

The hole diameter does not always gradually decrease from the upper section to the lower section. The memory hole (the columnar section CL) is sometimes formed in a bowing shape in which a portion having the largest hole diameter is formed halfway in the stacking direction.

In the memory hole having the bowing shape, the portion having the largest hole diameter is often formed further on the upper side than the center in the stacking direction. In the embodiment, the insulating layer thickness is controlled taking into account that effect.

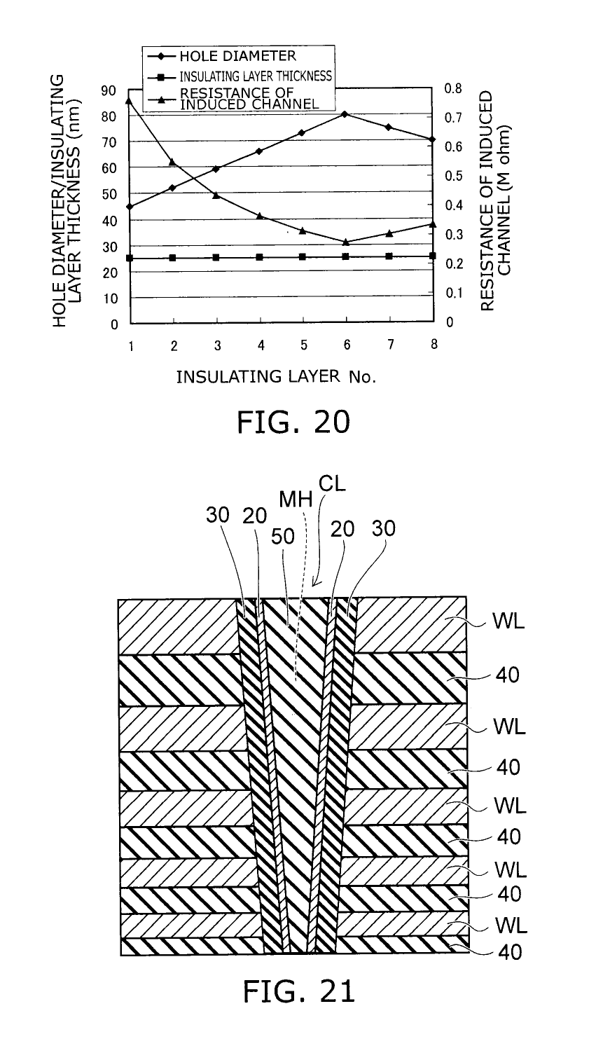

FIG. 20 is a graph representing a relation among the insulating layer No., a hole diameter (nm), the thickness (nm) of the insulating layer 40, and the resistance (M ohm) of the induced channel by the fringe electric field in a reference example with respect to the fifth embodiment in which the memory hole is formed in the bowing shape.

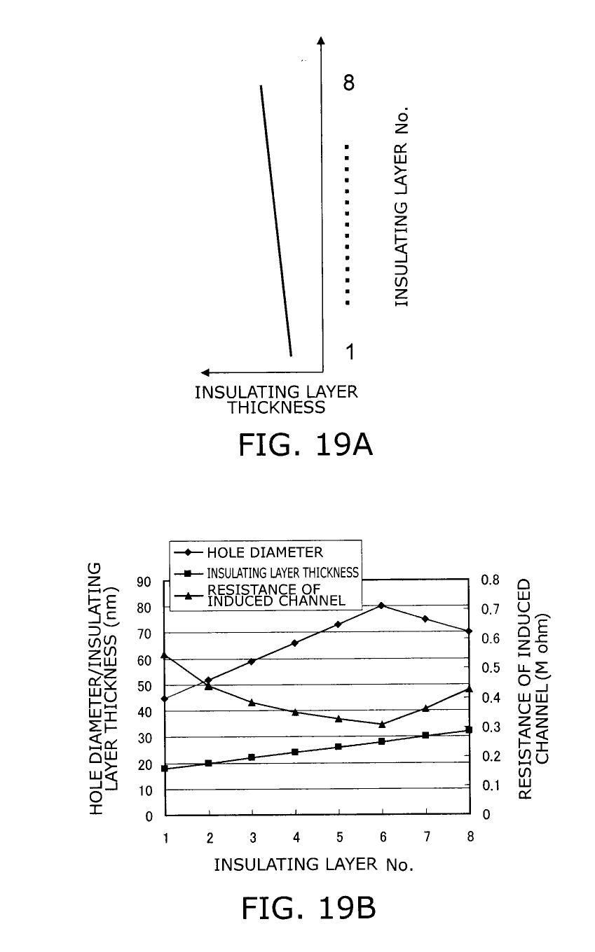

The hole diameter is the largest (80 nm) in the position of the sixth insulating layer 40 from the bottom (the second insulating layer 40 from the top). The same applies to the fifth embodiment represented in FIGS. 19A and 19B.

In the reference example of the bowing shape shown in FIG. 20, the total thickness of the eight insulating layers 40 is 200 nm. The thicknesses of the eight insulating layers 40 is the same fixed value (25 nm).

The parasitic resistance of the memory string (a total of channel resistances of the induced transistors) in the reference example shown in FIG. 20 is 3.34 MΩ.

FIG. 19A is a schematic view showing a thickness change in the stacking direction of the insulating layers 40 in the fifth embodiment. The abscissa represents the thicknesses of the insulating layers 40 and the ordinate represents layer numbers (insulating layer Nos.) of the insulating layers 40.

FIG. 19B is a graph representing a relation among the insulating layer No., the hole diameter (nm), the thickness (nm) of the insulating layer 40, and the resistance (M ohm) of the induced channel by the fringe electric field in the fifth embodiment.

In the fifth embodiment, the thicknesses of the eight insulating layers 40 linearly change as a linear function of the insulating layer No. That is, the thicknesses decrease in every layer from the eighth insulating layer 40 to the first insulating layer 40.

The thickness of the thickest eighth insulating layer 40 is 32 nm. The thickness of the thinnest first insulating layer 40 is 18 nm. A difference between a maximum and a minimum of the thicknesses of the insulating layers 40 is 14 nm.

The parasitic resistance of the memory string (a total of channel resistances of the induced transistors) in the fifth embodiment is 3.15 MΩ. The parasitic resistance of the third embodiment is 5.7% lower than that of the reference example.

Note that, if the portion having the largest hole diameter is formed further on the lower side than the center in the stacking direction in the memory hole having the bowing shape, contrary to the embodiment, it is desired to perform the thickness control of the insulating layers 40 such that the thicknesses increase in every layer from the eighth insulating layer 40 to the first insulating layer 40.

### Sixth Embodiment

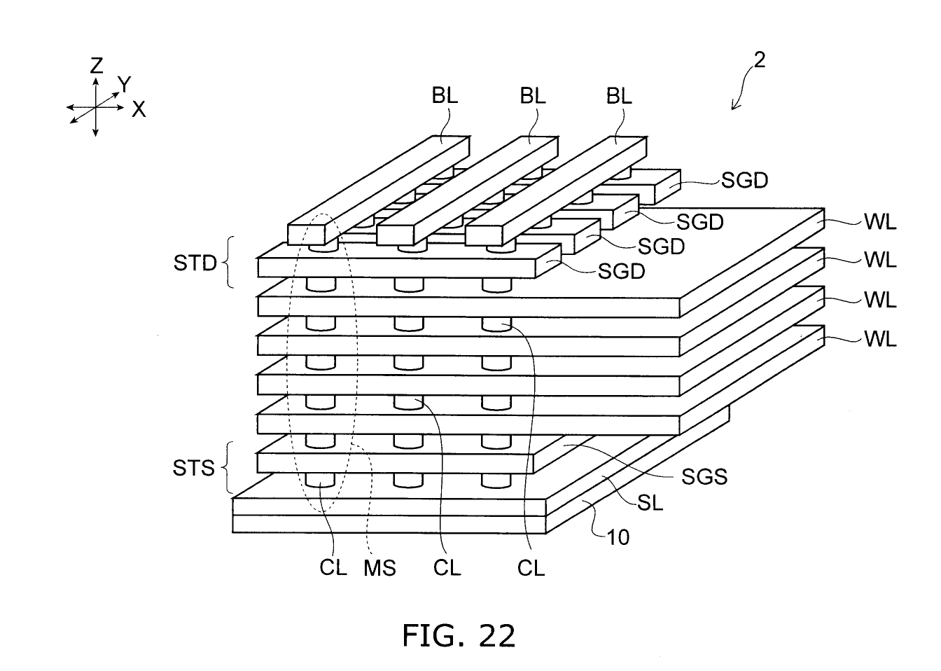

FIG. 21 is a schematic sectional view of a memory string in a sixth embodiment.

In the embodiments described above, the channel length of the transistor (the thickness of the insulating layer 40) induced in the region where the insulating layer 40 is formed under the situation in which the memory hole diameter is not uniform in the thickness direction is adjusted. This idea applies to not only the induced transistor but also the memory cell transistor in the region where the electrode layer WL is formed.

As shown in FIG. 21, the thicknesses of the electrode layers WL further on the lower side than the center in the stacking direction are smaller than the thicknesses of the electrode layers WL on the upper side. The thicknesses of the electrode layers WL adjacent to the lower section of the columnar section CL are smaller than the thicknesses of the electrode layers WL adjacent to the upper section of the columnar section CL.

If the hole diameter (the diameter of the columnar section CL) is large, the channel width of the memory cell transistor is large. Therefore, even if the electrode layers WL are formed thick (the channel length L is increased), an increase amount of channel resistance is not conspicuous.

On the other hand, if the hole diameter (the diameter of the columnar section CL) is small, the channel width of the memory cell transistor is small. Therefore, it is effective for a reduction in the resistance of the entire memory string to form the electrode layers WL thin (reduce the channel length), thereby decreasing the channel resistance.

FIG. 22 is a schematic perspective view of a memory cell array 2 of another example of the semiconductor memory device of the embodiment. Note that, in FIG. 22, as in FIG. 1, illustration of insulating layers and the like is omitted to clearly show the figure.

In FIG. 22, two directions parallel to the major surface of the substrate 10 and orthogonal to each other are represented as an X-direction and a Y-direction. A direction orthogonal to both of the X-direction and the Y-direction is represented as a Z-direction (a stacking direction).

The source layer SL is provided on the substrate 10. The source side selection gate (the lower selection gate) SGS is provided on the source layer SL via an insulating layer.

An insulating layer is provided on the source side selection gate SGS. On the insulating layer, a stacked body in which the plurality of electrode layers WL and a plurality of insulating layers are alternately stacked is provided.

An insulating layer is provided on the top electrode layer WL. The drain side selection gate (the upper selection gate) SGD is provided on the insulating layer.

The columnar section CL extending in the Z-direction is provided in the stacked body. That is, the columnar section CL pierces through the drain side selection gate SGD, the plurality of electrode layers WL, and the source side selection gate SGS. The upper end of the channel body 20 in the columnar section CL is connected to the bit line BL. The lower end of the channel body 20 is connected to the source line SL.

In the memory cell array 2 shown in FIG. 22, as in the embodiments described above, on the lower layer side where the channel width W of the channel induced in the inter-electrode region by the fringe electric field is small compared with the upper layer side, the thickness of the insulating layer 40 is set small compared with the upper layer side. That is, the channel length L of the induced channel on the lower layer side is set small compared with the upper layer-side. Consequently, it is possible to reduce a total of resistances of channels induced by the fringe electric field (the parasitic resistance of the memory string).

In the embodiments described above, the cylindrical memory cells are assumed. However, actually, the memory hole is often formed in, rather than a perfect circle, a shape (an elliptical shape or the like) deviating from the perfect circle. In that case, the diameter of the memory hole (the columnar section CL) can be defined as an effective diameter with respect to the area of the memory hole.

That is, when the area of the memory hole in the layers is represented as S and the effective diameter of the memory hole is represented as R, the effective diameter R of the memory hole can be obtained as an effective diameter suitable for the area S from a relational expression S=π(R/2)². Even when the memory hole deviates from the perfect circle, the memory string can be formed as in the embodiment on the basis of this R.

In the embodiments described above, the interlayer insulating layer is also present on the upper end side of the string (between the upper selection gate and the stacked body) or on the lower end side of the string (between the lower selection gate and the stacked body). Therefore, any one of the upper end side and the lower end side of the string may be taken into account when the parasitic resistance is estimated. In this case, superiority of the embodiments can also be exhibited compared with the reference examples. Note that, as the number of memory cells forming the string increases, it is less necessary to take into account the upper end side or the lower end side of the string.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A semiconductor memory device comprising:
a stacked body including a plurality of electrode layers stacked via an insulator; and
a columnar section including a channel body extending in a stacking direction of the stacked body in the stacked body, and a memory film provided between the channel body and the electrode layers,
the columnar section including a first region having a first diameter and a second region having a second diameter smaller than the first diameter,
the plurality of electrode layers including a first electrode layer adjacent to the first region and a second electrode layer adjacent to the first region, and a third electrode layer adjacent to the second region and a fourth electrode layer adjacent to the second region, and
a distance between the third electrode layer and the fourth electrode layer being smaller than a distance between the first electrode layer and the second electrode layer.

2. The device according to claim 1, wherein the columnar section includes an upper section and a lower section having a diameter smaller than a diameter of the upper section.

3. The device according to claim 2, wherein the third electrode layer and the fourth electrode layer are adjacent to the lower section.

4. The device according to claim 1, wherein
the first electrode layer and the second electrode layer are provided further on an upper side than a center of the stacked body in the stacking direction, and
the third electrode layer and the fourth electrode layer are provided further on a lower side than the center in the stacking direction.

5. The device according to claim 1, wherein
the channel body is formed in a cylindrical shape extending in the stacking direction, and
a circumferential direction length of the channel body further on a lower side than a center of the stacked body in the stacking direction is smaller than a circumferential direction length of the channel body further on an upper side than the center.

6. The device according to claim 1, wherein a thickness of the first electrode layer in the stacking direction and a thickness of the second electrode layer in the stacking direction are thicker than a thickness of the third electrode layer in the stacking direction and a thickness of the fourth electrode layer in the stacking direction.

7. A semiconductor memory device comprising:
a stacked body including a plurality of electrode layers stacked via an insulator; and
a columnar section including a channel body extending in a stacking direction of the stacked body in the stacked body, and a memory film provided between the channel body and the electrode layers,
the columnar section including a first region having a first diameter and a second region having a second diameter smaller than the first diameter,
the insulator including a first insulating layer adjacent to the first region and a second insulating layer adjacent to the second region, and
a thickness of the second insulating layer in the stacking direction being thinner than a thickness of the first insulating layer in the stacking direction.

8. The device according to claim 7, wherein
the first insulating layer is provided further on an upper side than a center of the stacked body in the stacking direction, and
the second insulating layer is provided further on a lower side than the center in the stacking direction.

9. The device according to claim 7, wherein
the channel body is formed in a cylindrical shape extending in the stacking direction, and
a circumferential direction length of the channel body further on a lower side than a center of the stacked body in the stacking direction is smaller than a circumferential direction length of the channel body further on an upper side than the center.

10. The device according to claim 7, wherein
the plurality of electrode layers include a first electrode layer adjacent to the first region and a second electrode layer adjacent to the second region, and
a thickness of the first electrode layer in the stacking direction is thicker than a thickness of the second electrode layer in the stacking direction.

11. The device according to claim 7, wherein the columnar section includes an upper section and a lower section having a diameter smaller than a diameter of the upper section.

12. The device according to claim 11, wherein the second insulating layer is adjacent to the lower section.

13. A semiconductor memory device comprising:
a stacked body including a plurality of electrode layers stacked via an insulator; and
a columnar section including a channel body extending in a stacking direction of the stacked body in the stacked body, and a memory film provided between the channel body and the electrode layers,
the columnar section including a first region having a first diameter and a second region having a second diameter smaller than the first diameter,
the insulator including a first insulating layer adjacent to the first region, a second insulating layer immediately above the first insulating layer, a third insulating layer adjacent to the second region, and a fourth insulating layer immediately above the third insulating layer, and
when a thickness of the third insulating layer in the stacking direction is represented as tᵢ, a thickness of the fourth insulating layer in the stacking direction is represented as tᵢ₊₁, a thickness of the first insulating layer in the stacking direction is represented as tⱼ, and a thickness of the second insulating layer in the stacking direction is represented as tⱼ₊₁, tᵢ₊₁−tᵢ>tⱼ₊₁−tⱼ.

14. The device according to claim 13, wherein
the first insulating layer and the second insulating layer are provided further on an upper side than a center of the stacked body in the stacking direction, and
the third insulating layer and the fourth insulating layer are provided further on a lower side than the center in the stacking direction.

15. The device according to claim 13, wherein
the channel body is formed in a cylindrical shape extending in the stacking direction, and
a circumferential direction length of the channel body further on a lower side than a center of the stacked body in the stacking direction is smaller than a circumferential direction length of the channel body further on an upper side than the center.

16. The device according to claim 13, wherein
the plurality of electrode layers include a first electrode layer adjacent to the first region and a second electrode layer adjacent to the second region, and
a thickness of the first electrode layer in the stacking direction is thicker than a thickness of the second electrode layer in the stacking direction.

17. The device according to claim 13, wherein the columnar section includes an upper section and a lower section having a diameter smaller than a diameter of the upper section.

18. The device according to claim 17, wherein the third electrode layer and the fourth electrode layer are adjacent to the lower section.
